(19) United States
(12) Patent Application Publication
(10) Pub. No.: US 2007/0096174 A1
(43) Pub. Date: May 3, 2007

(54) Semiconductor device having PN junction diode and method for manufacturing the same

(75) Inventor: Yasushi Higuchi, Okazaki-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/589,205

(22) Filed: Oct. 30, 2006

(30) Foreign Application Priority Data
Nov. 1, 2005 (JP) 2005-318729
Aug. 7, 2006 (JP) 2006-214936

(51) Int. Cl. H01L 29/76

(52) U.S. Cl. 257/288

(57) ABSTRACT

A semiconductor device includes: a semiconductor support substrate having a first conductive type; an insulation layer on the substrate; a semiconductor layer on the insulation layer; a semiconductor element in the semiconductor layer; and a first impurity diffusion region having a second conductive type. The first impurity diffusion region in the substrate contacts the insulation layer, and is isolated from the semiconductor layer with the insulation layer. The first impurity diffusion region and the substrate provide a PN junction diode. The semiconductor element has a maximum operation voltage, and the PN junction diode has an applied voltage opposite to a forward voltage and lower than the maximum operation voltage.

### CROSS REFERENCE TO RELATED APPLICATIONS

This application is based on Japanese Patent Applications No. 2005-318729 filed on Nov. 1, 2005, and No. 2006-214936 filed on Aug. 7, 2006, the disclosures of which are incorporated herein by reference.

### FIELD OF THE INVENTION

The present invention relates to a semiconductor device having a PN junction diode and a method for manufacturing the same.

### BACKGROUND OF THE INVENTION

In electronic control units mounted on, for example, industrial machines and automobiles, semiconductor apparatus (namely, hybrid devices) manufactured by integrating a plurality of semiconductor devices on semiconductor chips have been widely utilized for compactness purposes and power saving purposes. These plural semiconductor devices are known as MOS transistors, bipolar transistors, double diffused MOS transistors, and the like. In the above-explained semiconductor apparatus, in order to suppress mutual effects, latch-up, and the like, which occur among respective semiconductor apparatus, the respect semiconductor chips are required to be insulated and separated from each other. As one of insulating/separating structures, generally speaking, such a structure made by combining SOI (silicon on insulator) structures with trench structures is known in the technical field. In accordance with this insulating/separating structure, mutual effects and-latch up occurred among the above-explained respective semiconductor devices may be properly suppressed, and also, the respective semiconductor devices may be operated in higher speeds, under lower power consumption, at higher withstanding voltages, and furthermore, operating temperatures thereof may be improved, as compared with those of the conventional PN junction separation structures.

On the other hand, such high withstanding voltage characteristics, for instance, withstanding voltages exceeding several hundreds V (volts) to 1,000 V may be sometimes required in semiconductor apparatus, depending upon use fields of these semiconductor apparatus. In the case that the above-explained SOI structure is employed as structures of the above-described semiconductor apparatus required for such high withstanding voltage characteristics, when this high withstanding voltage is designed, a design freedom degree similar to that of such a case that a semiconductor device is formed in a bulk wafer may be secured as to a direction (lateral direction) which is parallel to a surface of the bulk wafer, whereas with respect to a vertical direction (longitudinal direction) which is vertical to the wafer surface, restrictions as to design aspects are made due to the below-mentioned reasons.

As represented in FIG. 27A, in a semiconductor apparatus as a related art formed in a bulk wafer, a depletion layer 105 is expanded from a drain higher concentration region 103 and a drain lower concentration region 104 in response to a voltage applied to a semiconductor device. On the other hand, as represented in FIG. 27B, in a semiconductor device provided within a semiconductor apparatus which employs the SOI structure, an embedded insulating film 112 has been formed between a semiconductor supporting substrate 110 and an SOI layer (semiconductor layer) 111. As a result, expansion of a depletion layer 115 from the drain higher concentration region 103 and the drain lower concentration region 104 is restricted within a predetermined range due to existence of the above-explained embedded insulating film 112. Then, in the semiconductor apparatus using the above-explained SOI structure, since voltages are applied to the depletion layer 115 and also the embedded insulating film 112, a withstanding voltage of the semiconductor apparatus is also determined based upon the thickness of the SOI layer 111 and the thickness of the embedded insulating film 112, which restricts the high withstanding voltage designing aspect.

Under such a circumstance, the following method capable of improving the withstanding voltage of the semiconductor apparatus may be conceived. That is, the thickness of the above-explained SOI layer and the thickness of the embedded insulating film are made thick in addition to the optimization of the impurity concentration in the semiconductor supporting substrate in order that the electric field concentration with respect to the SOI layer and the embedded insulating film may be relaxed so as to improve the withstanding voltage as the semiconductor apparatus. However, in order to achieve a withstanding voltage of, for instance, 1,000 V as the semiconductor apparatus, the thickness of the above-described SOI layer must be selected to approximately 50 μm, and the thickness of the embedded insulating film must be selected to be approximately 6 μm . As previously explained, in order to make the SOI layer thick, the depths of the trenches used to insulate and separate the respective semiconductor devices must be made deep. This may cause difficulties in the manufacturing method. In the worst case, there is a risk that the insulation and separations of the respective semiconductor devices become imperfect. Also, if the thickness of the embedded insulating film is made thick, then a camber amount of the SOI wafer before the semiconductor apparatus is also increased. As a result, such a problem newly occurs that the SOI wafer can be hardly processed.

As conventional semiconductor apparatus capable of solving such a problem and capable of improving the withstanding voltage thereof, one semiconductor apparatus recited in, for instance, U.S. Pat. No. 5,382,818 is known in the technical field. That exemplifies such a case that a MOS transistor is employed as a semiconductor device. As indicated in FIG. 28, this semiconductor apparatus (semiconductor device) owns a structure. That is, a PN junction diode 122 made of a semiconductor supporting substrate 120 and an impurity diffused region 121 is embedded/formed in the semiconductor supporting substrate 120, and further, an embedded insulating film 124 between this PN junction diode 122 and a drain higher concentration region 123 has been removed. When a voltage is applied to the semiconductor device under such a structure, a depletion layer of the PN junction portion of the above-explained PN junction diode 122 is expanded in response to a potential at the SOI layer 125. As a result, the withstanding voltage of the semiconductor apparatus may be improved only by a voltage portion which can be held by this depletion layer. It should be understood that this depletion layer is expanded not only to a portion in the vicinity of the PN junction portion of the PN junction diode 122, but also expanded to an entire lower concentration drain region in correspondence with potentials at the respective portions of the upper SOI layer. As a result, the high withstanding voltage of the semiconductor apparatus may be realized similar to that of a bulk wafer.

In addition, for example, another semiconductor apparatus described in U.S. Pat. No. 5,113,236 is known in this technical field. Similar to the above-described semiconductor apparatus recited in U.S. Pat. No. 5,382,818, this semiconductor apparatus owns such a structure that a PN junction diode is embedded and formed in a semiconductor supporting substrate, and a portion of an embedded insulating film which is contacted to an impurity diffused region of this PN junction diode has been removed. It should be understood that in this semiconductor apparatus, the above-explained PN junction diode has been formed at a place located apart from a semiconductor device in a device forming region (island) by an exclusively used separating trench. Moreover, an electrode has been formed on a surface of an SOI layer located above the PN junction diode. Then, within this SOI layer, a contact-purpose impurity diffused section having the same conductivity type as a conductivity type of the impurity diffused region of the PN junction diode has been formed in such a way that this contact-purpose impurity diffused section is connected to the electrode and the PN junction diode. Under such a structure, a voltage which is higher than, or equal to an applied voltage to the semiconductor device formed in the SOI layer is applied to the above-explained PN junction diode formed in this semiconductor apparatus through both the electrode and the contact-purpose impurity diffused section. As a result, also in the semiconductor apparatus, the higher withstanding voltage of the semiconductor apparatus is realized by expanding the depletion layer of the PN junction of the PN junction diode formed in the semiconductor supporting substrate.

On the other hand, in the above-described semiconductor apparatus, the drain higher concentration region 123 is electrically connected via the SOI layer 125 to the impurity diffused region 121, so that a voltage which is equivalent to the drain voltage is applied to the PN junction diode 122. In other words, the withstanding voltage of the semiconductor apparatus cannot be improved while this withstanding voltage is not higher than, or equal to the withstanding voltage of the PN junction diode 122. Also, in the semiconductor apparatus, although the voltage is applied which is different from the applied voltage to the semiconductor device via the contact-purpose impurity diffused section formed in the SOI layer, this applied voltage is higher than, or equal to the voltage applied to the semiconductor device. As a result, the withstanding voltage of the semiconductor apparatus cannot be improved, while this withstanding voltage is not higher than, or equal to the withstanding voltage of the PN junction diode which is embedded and formed.

### SUMMARY OF THE INVENTION

In view of the above-described problem, it is an object of the present disclosure to provide a semiconductor device having a PN junction diode. It is another object of the present disclosure to provide a method for manufacturing a semiconductor device.

According to a first aspect of the present disclosure, a semiconductor device includes: a semiconductor support substrate having a first conductive type; an insulation layer disposed on the substrate; a semiconductor layer disposed on the insulation layer; a semiconductor element disposed in the semiconductor layer; and a first impurity diffusion region having a second conductive type. The first impurity diffusion region is disposed in the substrate, contacts the insulation layer, and isolated from the semiconductor layer with the insulation layer. The first impurity diffusion region and the substrate provide a PN junction diode. The semiconductor element has a maximum operation voltage. The PN junction diode has an applied voltage, which is applied to the PN junction diode opposite to a forward voltage of the PN junction diode and lower than the maximum operation voltage of the semiconductor element.

In the above device, since the reverse voltage is applied to the PN junction diode in the substrate, the depletion layer also expands in the support substrate. Accordingly, the breakdown voltage of the semiconductor device increases by a voltage held by the depletion layer in the support substrate in addition to a voltage held by a normal depletion layer in the semiconductor layer and a voltage held by the insulation layer. Further, since the PN junction diode is isolated from the semiconductor layer by the insulation layer, the breakdown voltage of the semiconductor device is not limited by the breakdown voltage of the PN junction diode. Accordingly, it is possible to apply a high voltage higher than the breakdown voltage of the PN junction diode to the semiconductor device, so that the breakdown voltage of the semiconductor device is improved. Furthermore, since the reverse voltage lower than the applied voltage of the semiconductor device is applied to the PN junction diode, the electric field at the corner of the PN junction diode is reduced by a field plate effect. Thus, the breakdown voltage of the semiconductor device is much improved.

According to a second aspect of the present disclosure, a method for manufacturing the device defined as follows is provided.

The semiconductor device includes: a semiconductor support substrate having a first conductive type; an insulation layer disposed on the substrate; a semiconductor layer disposed on the insulation layer; a semiconductor element disposed in the semiconductor layer; a first impurity diffusion region having a second conductive type; and a conductor disposed in a first trench through a first insulation film. The first impurity diffusion region is disposed in the substrate, contacts the insulation layer, and isolated from the semiconductor layer with the insulation layer. The first impurity diffusion region and the substrate provide a PN junction diode. The semiconductor element has a maximum operation voltage. The PN junction diode has an applied voltage, which is applied to the PN junction diode opposite to a forward voltage of the PN junction diode and lower than the maximum operation voltage of the semiconductor element. The conductor penetrates the semiconductor layer and the insulation layer and connects to the first impurity diffusion region. The conductor is isolated from the semiconductor layer with the first insulation film, and the applied voltage is capable of being applied to the PN junction diode through the conductor.

The above method includes: forming the insulation layer on the substrate; forming the semiconductor layer on the insulation layer; forming the first trench to penetrate the semiconductor layer and the insulation layer and to reach the substrate; forming the first insulation film on an inner wall of the first trench; removing a part of the first insulation film, which is disposed on a bottom of the first trench; filling the first trench with poly crystal semiconductor material having the second conductive type; and diffusing a second conductive type impurity in the poly crystal semiconductor material into the substrate in order to form the first impurity diffusion region.

In the above method, the PN junction diode isolated from the semiconductor layer by the insulation layer is formed together with the poly crystal semiconductor material as the conductor in the first trench. Accordingly, the manufacturing cost of the device is reduced.

### BRIEF DESCRIPTION OF THE DRAWINGS

The above and other objects, features and advantages of the present invention will become more apparent from the following detailed description made with reference to the accompanying drawings. In the drawings:

FIG. 1A is a plan view showing a semiconductor device according to a first embodiment, and FIG. 1B is a cross sectional view showing the device taken along line IB-IB in FIG. 1A;

FIG. 2 is a schematic cross sectional view showing a model of the device;

FIG. 3 is a graph showing a relationship between a drain-diode voltage and a PN junction diode breakdown voltage in the model obtained by simulation result;

FIGS. 4A and 4B are equivalent potential distribution graphs showing a depletion layer in the device;

FIG. 5 is a cross sectional view explaining a method for manufacturing the device in FIGS. 1A and 1B;

FIG. 6 is a cross sectional view explaining the method for manufacturing the device;

FIG. 7 is a cross sectional view explaining the method for manufacturing the device;

FIG. 8 is a cross sectional view explaining the method for manufacturing the device;

FIG. 9A is a plan view showing a semiconductor device according to a second embodiment, and FIG. 9B is a cross sectional view showing the device taken along line IXB-IXB in FIG. 9A;

FIG. 10A is a plan view showing a semiconductor device according to a third embodiment, and FIG. 10B is a cross sectional view showing the device taken along line XB-XB in FIG. 10A;

FIG. 11 is a cross sectional view explaining a method for manufacturing the device in FIGS. 10A and 10B;

FIG. 12 is a cross sectional view explaining the method for manufacturing the device;

FIG. 13 is a cross sectional view explaining the method for manufacturing the device;

FIG. 14 is a cross sectional view showing a semiconductor device according to a modification;

FIG. 15 is a cross sectional view showing a semiconductor device according to a second modification;

FIG. 16A is a plan view showing a semiconductor device according to a third modification, and FIG. 16B is a cross sectional view showing the device taken along line XVIB-XVIB in FIG. 16A;

FIG. 17 is a cross sectional view showing a semiconductor device according to a fourth modification;

FIG. 18 is a cross sectional view showing a semiconductor device according to a fifth modification;

FIG. 19A is a plan view showing a semiconductor device according to a sixth modification, and FIG. 19B is a cross sectional view showing the device taken along line XIXB-XIXB in FIG. 19A;

FIG. 20A is a plan view showing a semiconductor device according to a seventh modification, and FIG. 20B is a cross sectional view showing the device taken along line XXB-XXB in FIG. 20A;

FIG. 21 is a cross sectional view showing a semiconductor device according to an eighth modification;

FIG. 22A is a plan view showing a semiconductor device according to a ninth modification, and FIG. 22B is a cross sectional view showing the device taken along line XXIIB-XXIIB in FIG. 22A;

FIG. 23 is a cross sectional view showing a semiconductor device according to a tenth modification;

FIGS. 24A to 24C are cross sectional views explaining a method for manufacturing the device in FIG. 23;

FIG. 25 is a cross sectional view showing a semiconductor device according to an eleventh modification;

FIGS. 26A to 26D are graphs showing a timing chart of each electric potential in the device in FIG. 25;

FIGS. 27A and 27B are cross sectional views showing a depletion layer in a semiconductor device according to a related art; and

FIG. 28 is a cross sectional view showing a semiconductor device according to a prior art.

### DETAILED DESCRIPTION OF THE PREFERRED EMBODIMENTS

(First Embodiment)

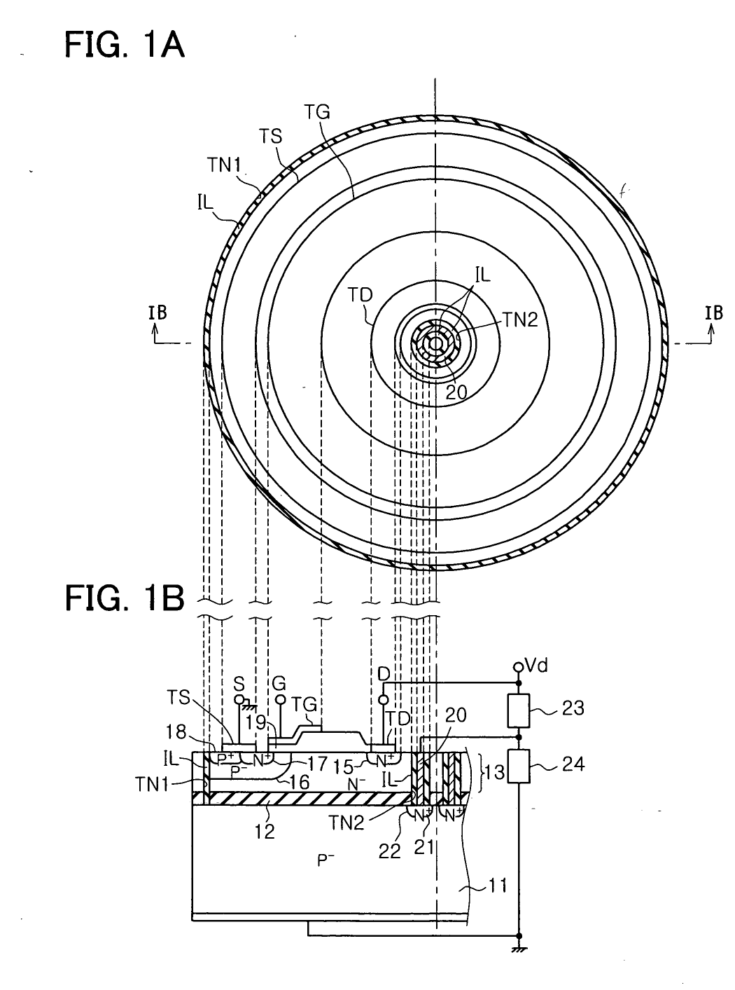

Referring now to FIG. 1A and FIG. 1B to FIG. 8, a description is made of a semiconductor apparatus and a manufacturing method thereof, according to a first embodiment.

Referring now to FIG. 1A and FIG. 1B, first of all, a detailed description is made of a structure of the semiconductor apparatus according to this first embodiment. It should be understood that FIG. 1A schematically shows a plane structure of a semiconductor device provided in this semiconductor apparatus, and FIG. 1B shows a portion as to a sectional structure of the semiconductor device, taken along a line IB-IB of FIG. 1A.

The semiconductor apparatus according to the first embodiment owns such a structure that, as shown in FIG. 1A, a plurality of semiconductor devices have been separated from each of elements by a circular-shaped element separating-purpose trench TN1. Then, a region surrounded by the element separating-purpose trench TN1 constitutes a device forming region. In this region, lateral type double diffused MOS transistors (namely, semiconductor devices) having respective electrodes have been formed, while these electrodes are a drain electrode TD, a gate electrode TG, and a source electrode TS arranged in a concentrical form. It should also be understood that an insulating film IL has been embedded in the element separating-purpose trench TN1, so that the above-explained lateral type double diffused MOS transistor has been electrically insulated from other semiconductor devices located around the lateral type double diffused MOS transistor.

Also, as represented in FIG. 1B, this semiconductor device has been basically constituted by having the below-mentioned structure. That is, an embedded insulating film 12 made of, for instance, a silicon oxide, and, for instance, an N type (second conductivity type) SOI layer (semiconductor layer) 13 have been sequentially stacked on, for example, a P type (first conductivity type) semiconductor supporting substrate 11.

An N type drain higher concentration region 15 whose concentration is higher than that of the above-explained SOI layer 13, a P type channel region 16, an N type source region 17 having the substantially same concentration as that of the drain higher concentration region 15, and a P type contact region 18 whose concentration higher than that of the channel region 16 have been formed on this SOI layer 13. It should also be noted that the P type contact region 18 has been provided in order to fix a channel potential.

Then, the drain electrode TD has been contacted in an ohmic junction manner on a surface of the drain higher concentration region 15. Also, the source electrode TS has been contacted in an ohmic junction manner on surfaces of the source region 17 and the contact region 18 in such a manner that this source electrode TS is contacted to these source region 17 and contact region 18. Furthermore, the gate electrode TG has been formed via a gate insulating film 19 made of a silicon dioxide on the surface of the channel region 16.

Also, a diode voltage applying-purpose trench TN2 has been formed in this SOI layer 13, while the diode voltage applying-purpose trench TN2 penetrates through both the SOI layer 13 and the embedded insulating film 12 and is reached to the semiconductor supporting substrate 11. An insulating film IL has been formed on an inner peripheral plane of the diode voltage applying-purpose trench TN2, and furthermore, an electric conductor 20 has been embedded in a portion inside the insulating film IL. The electric conductor 20 is made of, for example, polycrystal silicon which is a polycrystal semiconductor material. In other words, the electric conductor 20 insulated from the SOI layer 13 by the insulating film IL has been formed inside the diode voltage applying-purpose trench TN2.

Then, an N type (second conductive type) impurity diffused layer 21 whose concentration is higher than that of the SOI layer 13 has been embedded to be formed in a portion of the semiconductor supporting substrate 11, which is contacted to the embedded insulating film 12 in such a manner that this N type impurity diffused region 21 is electrically connected to the above-explained electric conductor 20. In the first embodiment, a PN junction diode 22 has been formed by the P type semiconductor supporting substrate 11 and the N type impurity diffused region 21. A reverse direction voltage which is lower than a drain voltage “Vd” applied to the drain electrode TD has been designed to be applied to the PN junction diode 22. It should also be noted that as represented in FIG. 1A, the diode voltage applying-purpose trench TN 2 has been formed in a ring shape at a central portion of the respective electrodes TS, TG, and TD arranged in the concentrical shape.

Concretely speaking, for example, as shown in FIG. 1B, while elements 23 and 24 such as resistors have been series-connected between the drain electrode TD and the ground, a voltage between these elements 23 and 24, namely a voltage sub-divided by the elements 23 and 24 has been designed to be applied via the electric conductor 20 to the PN junction diode 22. As a consequence, a reverse direction voltage which is lower than the drain voltage Vd applied to the above-explained drain electrode TD is applied to the PN junction diode 22.

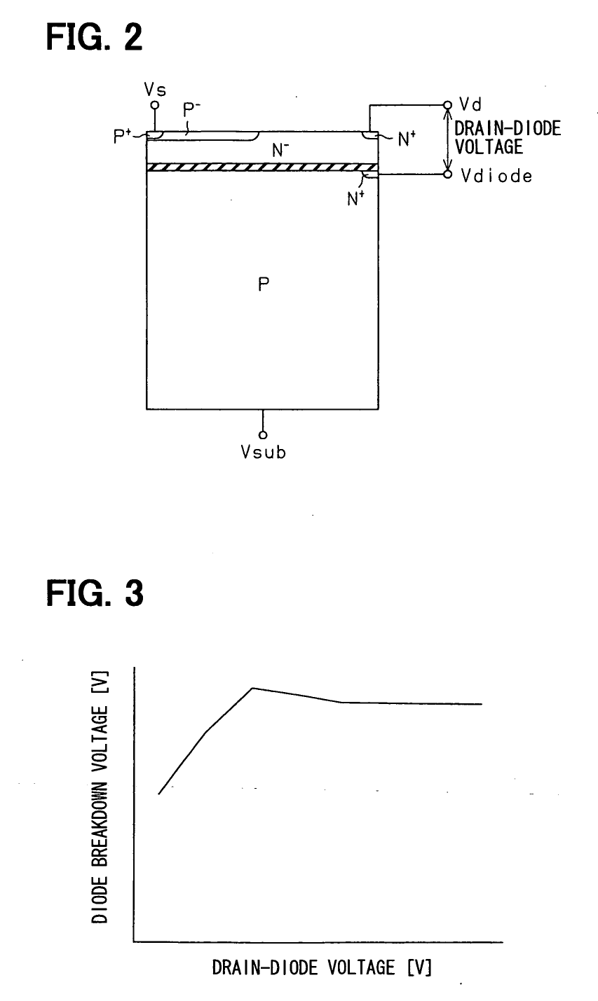

As previously explained, since the voltage lower than the drain voltage Vd applied to the drain electrode TD is applied with respect to the PN junction diode 22 formed in the semiconductor supporting substrate 11, a withstanding voltage of the lateral type double diffused MOS transistor can be made higher than the withstanding voltage (breakdown voltage) of the PN junction diode 22. Also, a voltage higher than the voltage applied to the PN junction diode 22 is applied with respect to the SOI layer 13 of the embedded insulating film 12, so that an electric field at the edge portion of the PN junction diode 22 may be relaxed due to a so-called “field plate effect.” As a consequence, the withstanding voltage of the PN junction diode 22 may be improved. This point will be explained in more detail with reference to FIG. 2 to FIG. 4.

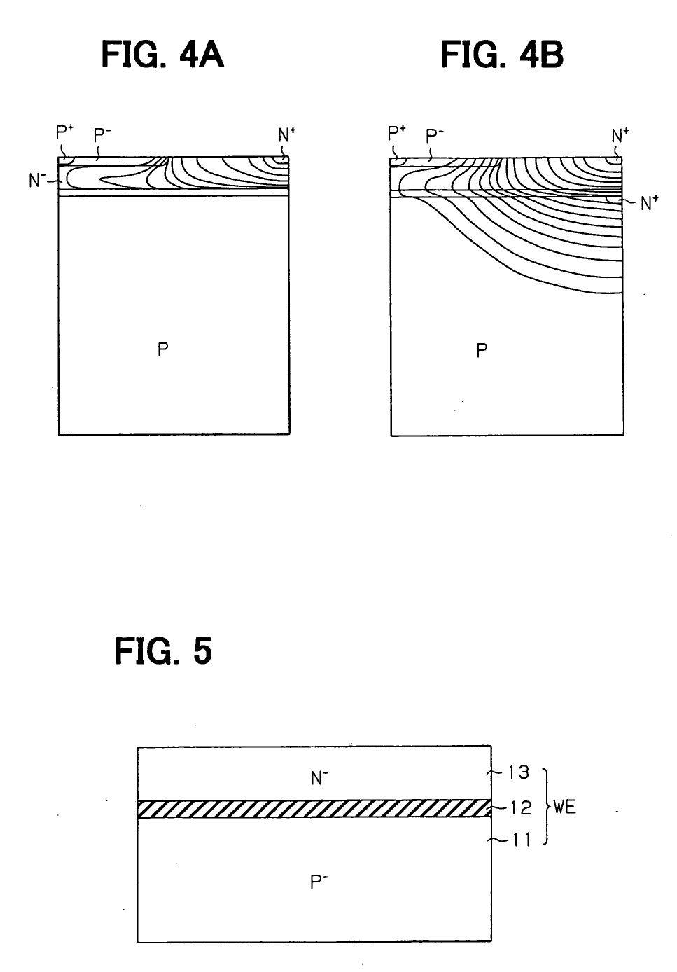

FIG. 2 schematically indicates the semiconductor device according to the first embodiment in a model form. In FIG. 2, a voltage “Vs” shows a source voltage; a voltage “Vd” represents a drain voltage; a voltage “Vsub ” indicates a substrate voltage; and a voltage “Vdiode” represents a voltage which is applied to an N type impurity diffused region of a PN junction diode, respectively. FIG. 3 indicates a result of simulation, namely, a relationship as to a voltage between the drain voltage Vd and the voltage Vdiode (will be referred to as “drain-to-diode voltage” hereinafter), and a withstanding voltage of the PN junction diode. Also, FIG. 4A and FIG. 4B represent results of simulation with respect to a difference in modes where depletion layers are widened, depending upon such a condition for indicating whether or not the PN junction diode within the semiconductor supporting substrate is present.

As shown in FIG. 3, in connection with such a condition that the drain-to-diode voltage is increased, the withstanding voltage of the PN junction diode is improved due to a so-called “field plate effect,” and thereafter, is saturated. As can be understood from this simulation result, in order to improve the withstanding voltage of the PN junction diode, it is effective that the drain-to-diode voltage is increased and the filed plate effect is developed.

Also, as indicated in FIG. 4A, in the conventional semiconductor device in which the PN junction diode of this first embodiment is not formed in the semiconductor supporting substrate, the expansion of the depletion layer in the SOI layer is restricted by the embedded insulating film. To the contrary, in such a case that the PN junction diode of this first embodiment has been formed in the semiconductor supporting substrate, as shown in FIG. 4B, the depletion layer in the semiconductor device becomes larger than the deletion layer shown in FIG. 4A due to both the depletion layer of the SOI layer and the depletion layer of the PN junction diode in the semiconductor supporting substrate. As a result, the voltage which can be held in the depletion layer is increased, so that the withstanding voltage of the semiconductor apparatus may be improved, or increased.

By the way, assuming now that the withstanding voltage of the PN junction diode is A [V], the withstanding voltage of the referred semiconductor apparatus becomes A [V] even at maximum, which is equal to the withstanding voltage of this PN junction diode. To the contrary, in such a case that the PN junction diode of the first embodiment has been formed in the semiconductor supporting substrate, assuming now that the improved withstanding voltage portion of the PN junction diode due to the field plate effect is B [V], and the drain-to-diode voltage is C [V], a withstanding voltage E [V] of the semiconductor apparatus becomes E=A+B+C. In other words, such a lower voltage than the voltage applied to the drain electrode is applied with respect to the PN junction diode formed in the semiconductor supporting substrate. As a result, the voltage which is higher than, or equal to the withstanding voltage of the PN junction diode can be applied to the semiconductor device as the drain voltage, and thus, the designing restriction as to the vertical direction (longitudinal direction) of the semiconductor apparatus can be annulled.

Next, manufacturing steps of the semiconductor apparatus according to the first embodiment will now be described in detail with reference to FIG. 5 to FIG. 8. FIG. 5 to FIG. 8 schematically show sectional structures of the semiconductor apparatus according to the first embodiment in accordance with manufacturing process.

Firstly, an SOI wafer (SOI substrate) “WE” shown in FIG. 5 is prepared. Precisely speaking, an embedded insulating film 12 having a thickness of approximately 0.1 to 4 μm and made of a silicon dioxide is formed on a P type semiconductor supporting substrate 11, the impurity concentrate of which is approximately 10¹³ to 10¹⁵ cm⁻³; an N type semiconductor substrate is pasted on the upper plane of the embedded insulating film 12; and further, the pasted N type semiconductor substrate is polished, so that an N type SOI layer 13 having a thickness of approximately 0.01 to 30 μm is formed. It should also be noted that while the method for manufacturing this SOI wafer WE is arbitrarily selectable, for example, instead of the method by the above-explained pasting way, the SOI wafer WE may be alternatively manufactured by an SIMOX (silicon implanted oxide).

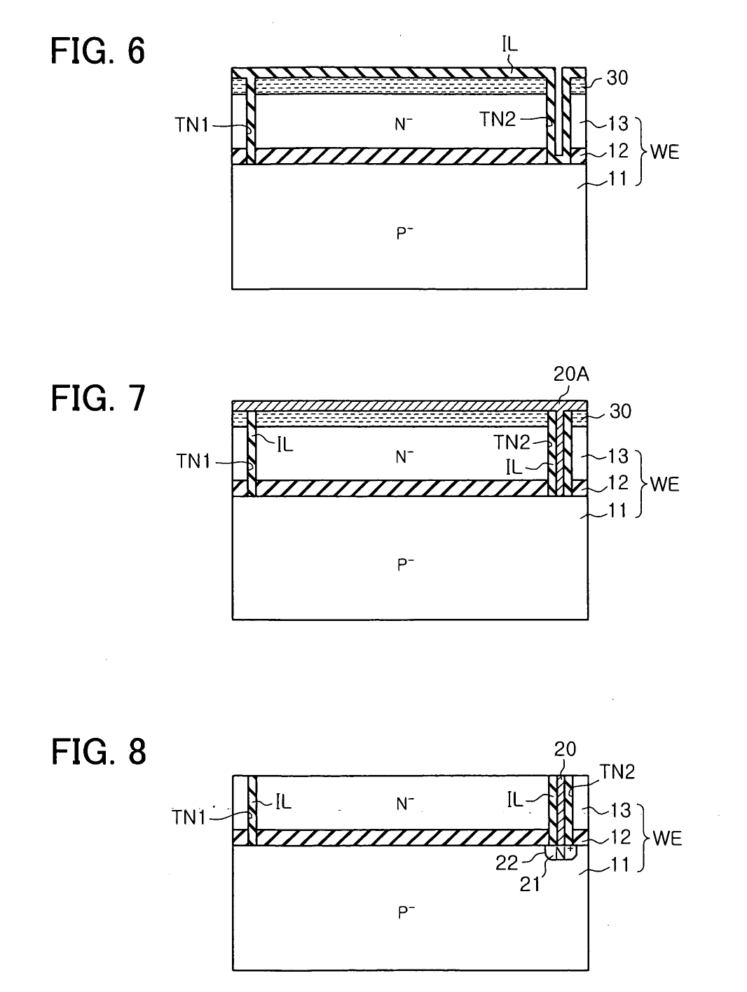

Next, as shown in FIG. 6, an insulating layer 30 is formed on the upper plane of the SOI wafer WE. Thereafter, both an element separating-purpose trench TN1 which passes through both the SOI layer 13 and the embedded insulating film 12 and is reached to the semiconductor supporting substrate 11, and a diode voltage applying-purpose trench TN2 which similarly passes through both the SOI layer 13 and the embedded insulating film 12 and is reached to the semiconductor supporting substrate 11 are formed by way of a pattern etching process. In this case, a width of the diode voltage applying-purpose trench TN2 has been set to be wider than that of the element separating-purpose trench TN1. Then, an insulating film IL having a thickness of approximately 0.3 to 2 μm is formed by way of either a thermal oxidizing method or a CVD (chemical vapor deposition) method so as to embed the element separating-purpose trench TN1 by this insulating film IL, and also to form the insulating film IL on an inner wall of the diode voltage applying-purpose trench TN2.

Next, as shown in FIG. 7, since the upper plane of the SOI wafer WE is etched, the insulating film IL formed on the upper plane of the insulating layer 30 is removed, and while the insulating film IL on the side wall of the diode voltage applying-purpose trench TN2 is left, the insulating film IL of the bottom portion thereof is removed. Then, a polycrystal silicon film 20A is formed so as to embed the diode voltage applying-purpose trench TN2 by this film 20A. When this polycrystal silicon film 20A is formed, an N type impurity is added. As a result, the polycrystal silicon film 20A into which the N type impurity has been added is filled into the internal portion of the diode voltage applying-purpose trench TN2. It should also be noted that adding of the N type impurity to this polycrystal silicon film 20A may be carried out after the polycrystal silicon film 20A has been formed. In addition, the polycrystal silicon film 20A on the upper plane of the insulating layer 30 is removed.

Thereafter, since a thermal processing operation is carried out, the N type impurity is diffused into the semiconductor supporting substrate 11 from the polycrystal silicon film 20A into which the N type impurity has been added. As a result, as shown in FIG. 8, an N type impurity diffused region 21 is formed in the semiconductor supporting substrate 11, and thus, a PN junction diode 22 is formed inside the semiconductor supporting substrate 11. Then, since an insulating layer 30 is removed, an electric conductor 20 is formed inside the diode voltage applying-purpose trench TN 2. It should also be noted that within the region surrounded by the above-explained element separating-purpose trench TN1, such a region except for the region surrounded by the diode voltage applying-purpose trench TN2 constitutes a device forming region, and respective regions such as a drain higher concentration region 15 are formed in this device forming region.

On the other hand, among the steps for forming the PN junction diode 22 in the semiconductor supporting substrate 11, the step for forming the insulating film IL on the inner wall of the diode voltage applying-purpose trench TN2 may be performed by adding two changes to a step for forming a trench separation structure which is generally carried out as an insulating separation in the SOI wafer WE. In other words, the diode voltage applying-purpose trench TN2 is formed by such a manner that when a trench is formed by an etching process operation, the embedded insulating film 12 is etched away in addition to the SOI layer 13, and the insulating film IL formed on the trench bottom portion is removed by way of an etching process operation. As a consequence, the manufacturing cost of the semiconductor apparatus may also be suitably suppressed.

As previously explained, in accordance with the semiconductor apparatus and the manufacturing method thereof related to the above-explained first embodiment, the below-mentioned effects can be achieved.

(1) The N type impurity diffused region 21 was embedded within the P type semiconductor supporting substrate 11 under such a condition that the N type impurity diffused region 21 was contacted to, and electrically isolated from the embedded insulating film 12, so that the PN junction diode 22 was fabricated by this N type impurity diffused region 21 and the P type semiconductor supporting substrate 11. Then, the reverse direction voltage which is lower than the drain voltage “Vd” was designed to be applied to the above-explained PN junction diode 22. In a wide sense, the above-explained reverse direction voltage implies a reverse direction voltage which is lower than a maximum operating voltage applied to a semiconductor device (will be discussed later in detail). As a result, when the voltage is applied to the semiconductor apparatus, the depletion layer is also expanded into the semiconductor supporting substrate 11, so that the withstanding voltage of the semiconductor apparatus may be improved by such a voltage portion which may be held by the depletion layer expanded into the semiconductor supporting substrate 11, as compared with the withstanding voltage set based upon the voltage which can be held by the depletion layer and the embedded insulating film within the conventional SOI layer. Moreover, since such a structure is employed that both the PN junction diode 22 and the SOI layer 13 are electrically insulated by the embedded insulating film 12, there is no possibility that the withstanding voltage of the semiconductor apparatus is limited by the withstanding voltage of the PN junction diode 22, although this limitation appears in the conventional semiconductor apparatus. As a consequence, the drain voltage “Vd” which is higher than the withstanding voltage of the PN junction diode 22 may be applied to the semiconductor apparatus, and thus, the withstanding voltage of the semiconductor apparatus may be furthermore improved by way of the withstanding voltage design along the lateral direction, which owns the relatively high design freedom degree.

Also, since the reverse-direction voltage lower than the drain voltage “Vd” is applied to the PN junction diode 22, the electric field at the corner portion of the PN junction diode 22 may be relaxed due to the so-called “field plate effect.” As a consequence, the withstanding voltage of the PN junction diode 22 itself can be improved. This point may contribute the improvement in the withstanding voltage of the semiconductor apparatus.

(2) Among the steps for forming the PN junction diode 22 in the semiconductor supporting substrate 11, the step for forming the insulating film IL on the inner wall of the diode voltage applying-purpose trench TN2 could be performed by adding two changes to the step for forming a trench separation structure which is generally carried out as the insulating separation in the SOI wafer. As a consequence, the manufacturing cost of the semiconductor apparatus may be suitably suppressed. By the way, in the conventional semiconductor apparatus, after the embedded diode has been formed in the semiconductor supporting substrate, the SOI layer must be formed on the embedded insulating film by way of an epitaxial growth, or the like, so that the manufacturing steps become complex. Also, in the conventional semiconductor apparatus, in order to connect the impurity diffused region formed in the semiconductor supporting substrate to the electrode formed on the surface of the SOI layer, the exclusively used trench for arranging the contact-purpose impurity diffused section must be formed. As a result, the manufacturing steps also become complex. In accordance with any of these conventional semiconductor apparatus, although the withstanding voltages thereof may be firmly improved, the manufacturing cost is increased due to the complex manufacturing steps.

(3) The drain voltage “Vd” is divided by the elements 23 and 24 which are series-connected between the drain voltage “Vd” and the ground, and then, this divided voltage is applied via the electric conductor 20 to the PN junction diode 22 as the reverse direction voltage. As a consequence, with employment of the simple structure, the reverse direction voltage which is lower than the applied voltage (drain voltage Vd) to the semiconductor apparatus can be firmly applied with respect to the PN junction diode 22.

(Second Embodiment)

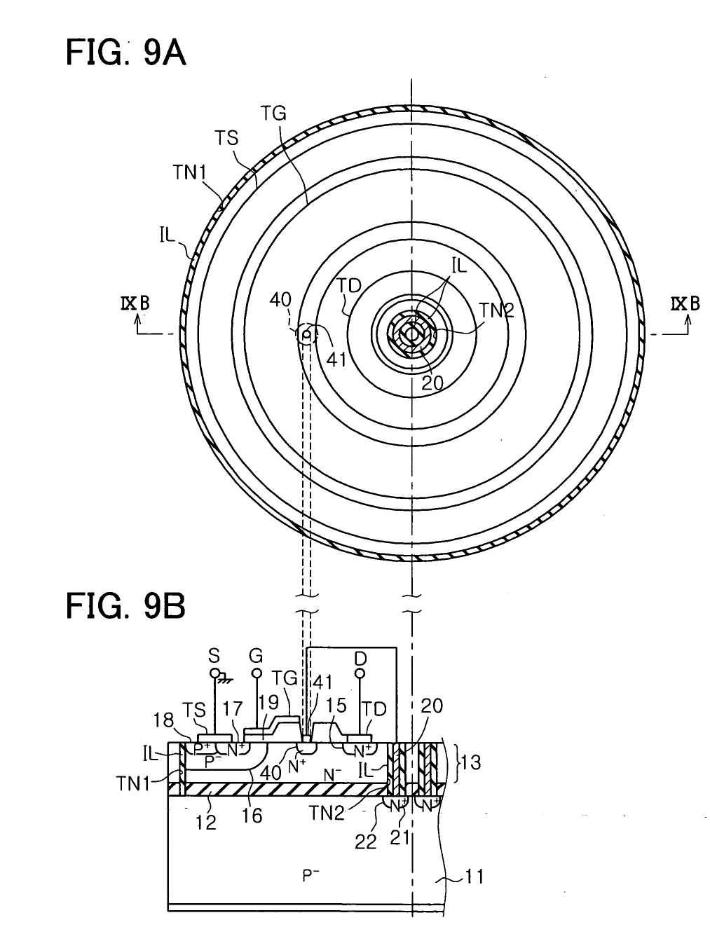

Next, a semiconductor apparatus according to a second embodiment will now be explained with reference to FIG. 9A and FIG. 9B.

As shown in FIG. 9A and FIG. 9B, in the semiconductor apparatus according to this second embodiment, an N type voltage extracting-purpose diffusion region 40 whose concentration is higher than that of the SOI layer 13 has been formed in a drift region between a drain higher concentration region 15 and a channel region 16 in an SOI layer 13. Then, a voltage extracting-purpose electrode 41 has been contacted to this voltage extracting-purpose diffusion region 40 in an ohmic contact manner, while the voltage extracting-purpose electrode 41 has been electrically connected to the electric conductor 20. In other words, the semiconductor apparatus according to this second embodiment is further provided with a voltage extracting-purpose electrode 41 between a drain electrode TD and a source electrode TS.

On the other hand, in connection with a voltage applied to the semiconductor apparatus, a voltage gradient is formed in a drift region which constitutes a current path. A magnitude of a voltage which is extracted by the voltage extracting-purpose electrode 41 is determined based upon a forming position of the voltage extracting-purpose diffusion region 40 in the drift region. As a consequence, the forming position of the voltage extracting-purpose diffusion region 40 in the drift region is changed, so that an arbitrary voltage lower than the drain voltage Vd can be extracted via the voltage extracting-purpose electrode 41.

As previously explained, in accordance with the semiconductor apparatus and the manufacturing method thereof related to this second embodiment, the below-mentioned effect may be achieved in addition to the above-described effects (1) and (2).

(4) The N type voltage extracting-purpose diffusion region 40 having the higher concentration than the concentration of the SOI layer 13 has been formed in the drift region between the drain higher concentration region 15 and the channel region 16, and also, the voltage extracting-purpose electrode 41 has been joined to this voltage extracting-purpose diffusion region 40. Then, this voltage extracting-purpose electrode 41 has been electrically connected to the electric conductor 20. As a result, even through the elements 23 and 24 in the semiconductor apparatus according to the first embodiment are not employed, the voltage lower than the drain voltage vd can be applied to the PN junction diode 22 via the voltage extracting-purpose electrode 41. Also, a magnitude of a voltage which is extracted by the voltage extracting-purpose electrode 41 is determined based upon a forming position of the voltage extracting-purpose diffusion region 40 in the drift region.

As a consequence, such a voltage having an arbitrary magnitude may be applied to the PN junction diode 22 by setting the forming position of the voltage voltage-purpose diffusion region 40 (voltage extraction-purpose electrode 41).

(Third Embodiment)

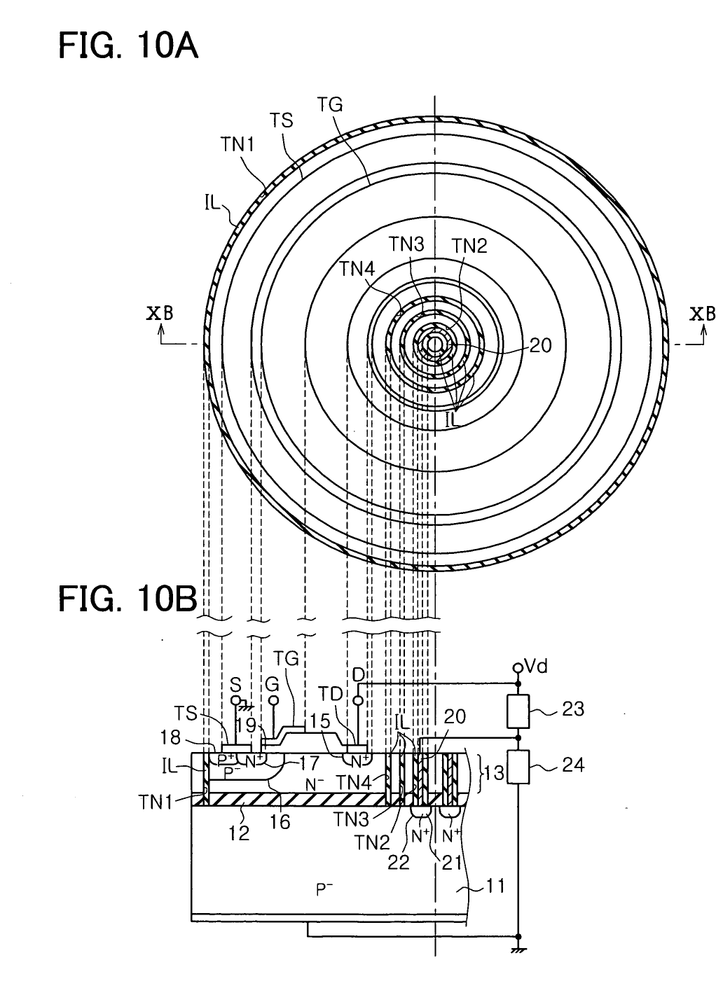

Next, a semiconductor apparatus according to a third embodiment will now be explained with reference to FIG. 10A and FIG. 10B to FIG. 13.

In the above-described semiconductor apparatus according to the first and second embodiments, when a potential difference between the above-explained electric conductor and the above-described SOI layer is large, it is preferable to make the thick insulating film of the inner wall of the diode voltage applying-purpose trench in order to secure the insulating separation withstanding voltage between the electric conductor and the SOI layer. In order to form such a thick thickness of the insulating film, there are many difficulties in view of the manufacturing process. Under such a circumstance, in the semiconductor apparatus of this third embodiment, a plurality of trenches are formed in a concentrical manner around the diode voltage applying-purpose trench, and also, insulating films are filled in the trenches, so that a voltage applied to the insulating film filled in the inner wall of the diode voltage applying-purpose trench may be reduced.

As represented in FIG. 10A, in the semiconductor apparatus according to this third embodiment, a trench TN3 and another trench TN4 have been formed in such a manner that these trenches TN3 and TN4 surround a diode voltage applying-purpose trench TN2. These trenches TN3 and TN4 are arranged in a concentrical manner, and own widths which are narrower than the width of this diode voltage applying-purpose trench TN2. As indicated in FIG. 10B, these trenches TN3 and TN4 have been formed in such a manner that these trenches TN3 and TN4 penetrate through both the SOI layer 13 and the embedded insulating film 12 and are reached to the semiconductor supporting substrate 11. Also, an insulating film IL has been embedded in these trenches TN3 and TN4. In other words, the semiconductor apparatus of this third embodiment is further equipped with the insulating film IL which penetrates through the SOI layer 13 and is reached to the embedded insulating film 12 around the electric conductor 20.

Under the above-explained structure, a capacitance coupling effect is established between the insulating film IL formed on the inner wall of the diode voltage applying-purpose trench TN2 and the insulating film IL embedded in the trench TN3, and a capacitance coupling effect is established between the insulating film IL embedded in the trench TN3 and the insulating film IL embedded in the trench TN4. As a consequence, a potential difference between the electric conductor 20 and the SOI layer 13 around this electric conductor 20 may be reduced. As a result, while the above-explained insulating separation withstanding voltage is maintained, it is possible to suppress an increase of the thickness of the insulating film IL formed in the inner wall of the diode voltage applying-purpose trench TN2. Concretely speaking, for example, in such a case that the potential difference between the electric conductor 20 and the SOI layer 13 is large, in order to obtain an insulation withstanding voltage between these structural elements 20 and 13, there are some possibilities that an insulating film having such a thick thickness as several μm is required to be formed as the insulating film IL formed on the inner wall of the diode voltage applying-purpose trench TN2, and a problem may occur in the treating characteristic of the insulating film. In contrast to the above-explained problem, in accordance with the semiconductor apparatus of this third embodiment, the insulation withstanding voltage can be secured by, for example, an insulating film having a thickness of approximately 0.5 to 1 μm.

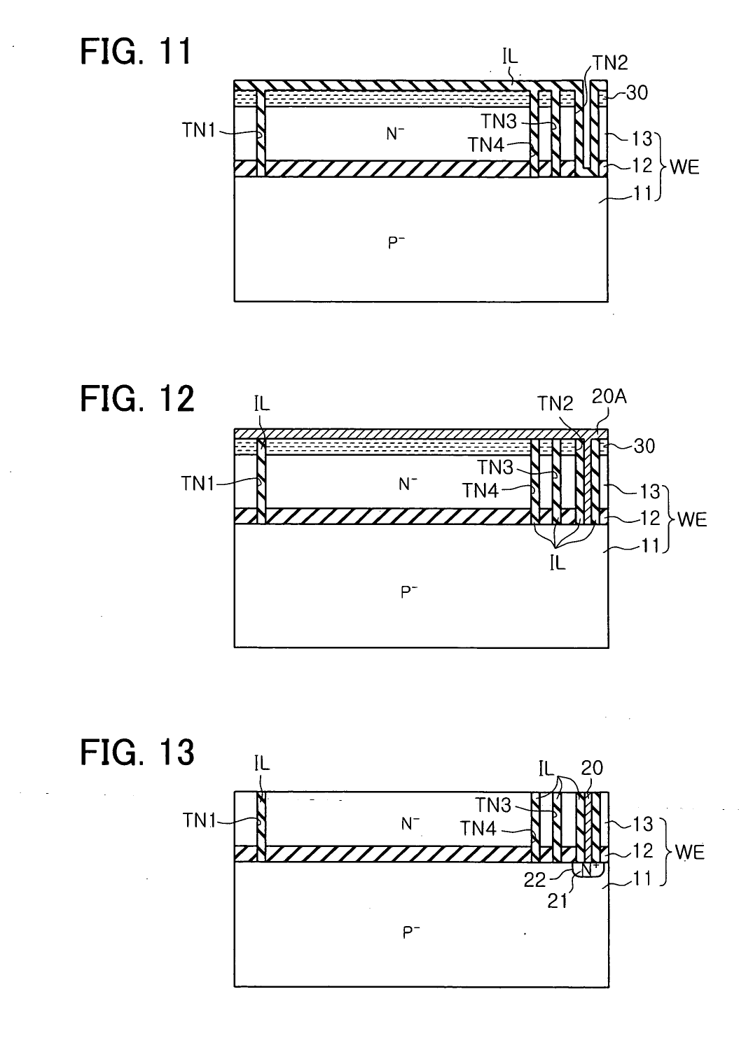

Next, referring now to FIG. 11 to FIG. 13, a description is made of manufacturing steps until the above-explained trenches TN1 to TN4 among steps for manufacturing the semiconductor apparatus according to this third embodiment. FIG. 11 to FIG. 13 schematically show sectional structures of the semiconductor apparatus according to the third embodiment in accordance with manufacturing process.

As represented in FIG. 11, an insulating layer 30 is formed on an upper plane of an SOI wafer WE manufactured in correspondence with the manufacturing method of the semiconductor apparatus according to the first embodiment. Thereafter, element separating-purpose trenches TN1, TN3, and TN4 are formed, and a diode voltage applying-purpose trench TN2 are formed by executing a pattern etching process. The element separating-purpose trenches TN1, TN3, and TN4 penetrate through the SOI layer 13 and the embedded insulating film 12 and then are reached to the semiconductor supporting substrate 11. The diode voltage applying-purpose trench TN2 similarly passes through both the SOI layer 13 and the embedded insulating film 12 and is reached to the semiconductor supporting substrate 11. In this case, a width of the diode voltage applying-purpose trench TN2 has been set to be wider than widths of the element separating-purpose trenches TN1, TN3, and TN4. Then, an insulating film IL having a thickness of approximately 0,3 to 2 μm is formed by way of either a thermal oxidizing method or a CVD (chemical vapor deposition) method so as to embed the element separating-purpose trenches TN1, TN3, TN4 by this insulating film IL, and also to form the insulating film IL on an inner wall of the diode voltage applying-purpose trench TN2.

Next, as shown in FIG. 12, since the upper plane of the SOI wafer WE is etched, the insulating film IL formed on the upper plane of the insulating layer 30 is removed, and while the insulating film IL on the side wall of the diode voltage applying-purpose trench TN2 is left, the insulating film IL of the bottom portion thereof is removed. Then, a polycrystal silicon film 20A is formed so as to embed the diode voltage applying-purpose trench TN2 by this film 20A. When this polycrystal silicon film 20A is formed, an N type impurity is added. As a result, the polycrystal silicon film 20A into which the N type impurity has been added is filled into the internal portion of the diode voltage applying-purpose trench TN2. It should also be noted that similar to the previously-explained first embodiment, adding of the N type impurity to this polycrystal silicon film 20A may be carried out after the polycrystal silicon film 20A has been formed. In addition, the polycrystal silicon film 20A on the upper plane of the insulating layer 30 is removed.

Thereafter, since a thermal processing operation is carried out, the N type impurity is diffused into the semiconductor supporting substrate 11 from the polycrystal silicon film 20A into which the N type impurity has been added. As a result, as shown in FIG. 13, an N type impurity diffused region 21 is formed in the semiconductor supporting substrate 11, and thus, a PN junction diode 22 is formed inside the semiconductor supporting substrate 11. Then, in this third embodiment, within the region surrounded by the above-explained element separating-purpose trench TN1, such a region except for the region surrounded by the diode voltage applying-purpose trench TN4 constitutes a device forming region, and respective regions such as a drain higher concentration region 15 are formed in this device forming region.

As previously explained, in accordance with the semiconductor apparatus and the manufacturing method thereof related to this third embodiment, the below-mentioned effect may be achieved in addition to the above-described effects (1) to (3).

(5) The trenches TN3 and TN4 which penetrate through the SOI layer 13 and are reached to the embedded insulating film 12 are formed around the diode voltage applying-purpose trench TN2 in the concentrical manner, and furthermore, the insulating film IL is filled in these trenches TN3 and TN4. As a consequence, the potential difference between the electric conductor 20 and the SOI layer 13 formed around this electric conductor 20 can be reduced via the capacitance coupling effects among the respective trenches TN2 to TN4. As a result, even in such a case that the potential difference between the electric conductor 20 and the SOI layer 13 is large, it is possible to suitably suppress that the thickness of the insulating film IL formed on the inner wall of the diode voltage applying-purpose trench TN2 is increased.

(Modifications)

It should also be understood that the above-explained semiconductor apparatus and manufacturing methods thereof are not limited only to the structures and the manufacturing methods thereof, which are represented as the above-explained respective embodiments, but the above-explained embodiments may be properly changed as follows:

That is, in the above-explained first embodiment, while the drain voltage Vd has been divided by the elements 23 and 24, this divided voltage has been applied via the electric conductor 20 to the PN junction diode 22. However, if the reverse direction voltage to be applied to the PN junction diode 22 is lower than the drain voltage Vd, then this reverse direction voltage may be arbitrarily set. For instance, a voltage which is lower than the drain voltage Vd may be alternatively applied from a power supply of a system which is different from the system of the drain voltage Vd via the electric conductor 20 to the PN junction diode 22.

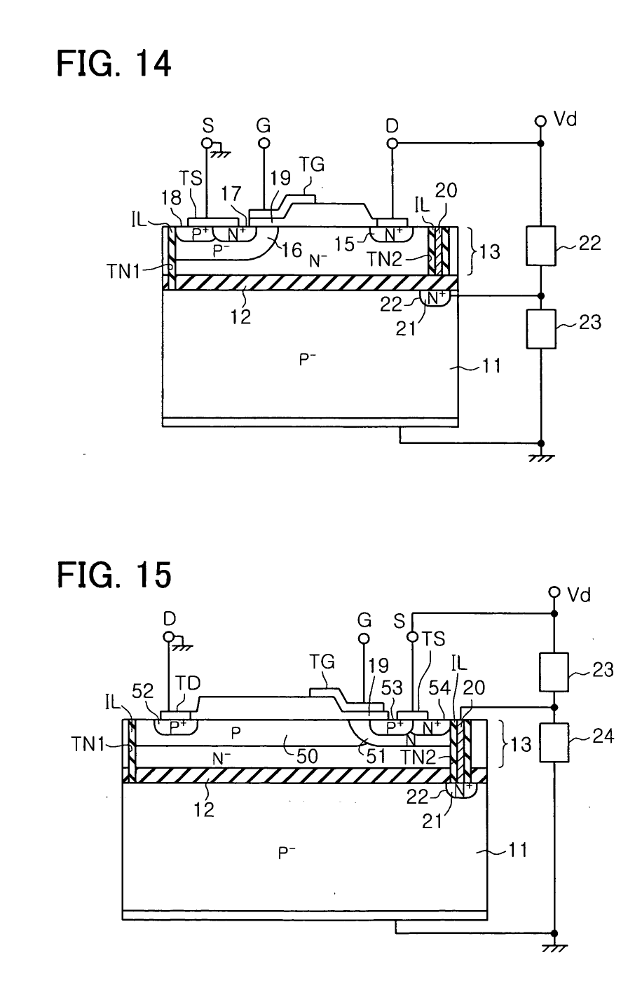

In the above-described first embodiment, the voltage “Vdiode” is applied via the electric conductor 20 to the PN junction diode 22. The structure used to apply the voltage “Vdiode” to the PN junction diode 22 is arbitrarily selected. For example, as represented in FIG. 14, the voltage “Vdiode” divided by the elements 23 and 24 may be directly applied to the PN junction diode 22 without via the electric conductor 20. In this alternative case, a wiring line from the impurity diffused region 21 up to the voltage dividing point between the elements 23 and 24 must be separately formed within the semiconductor supporting substrate 11.

In the third embodiment, a voltage which is lower than the drain voltage Vd may be alternatively applied from the external source with respect to the SOI layer 13 between the diode voltage applying-purpose trench TN2 and the trench TN3, and also to the SOI layer 13 between the trench TN3 and the trench TN4. Even when such a voltage applying structure is employed, a similar effect to the above-explained effect (5) may be achieved.

In the third embodiment, the trenches TN3 and TN4 have been formed in such a manner that these trenches TN3 and TN4 penetrate through the SOI layer 13 and the embedded insulating film 12 and are reached to the semiconductor supporting substrate 11. However, these trenches TN3 and TN4 need not be always formed in such a manner that the trenches TN3 and TN4 are reached to the semiconductor supporting substrate 11 if the following condition can be satisfied. That is, if the insulating film IL may be formed within the trenches TN3 and TN4, and this film IL may penetrate through the SOI layer 13 to be reached to the embedded insulating film 12, then widths and depths of the trenches TN3 and TN4 may be arbitrarily set. Even in this alternative case, capacitance coupling effects may be produced among the respective insulating films IL of the trenches TN2, TN3, TN4, so that a potential difference between the electric conductor 20 and the SOI layer 13 formed around this electric conductor 20 may be suitably reduced. Further, the structures of the trench TN3 and TN4 may be alternatively made similar to the structure of the diode voltage applying-purpose trench TN2. In other words, the insulating film IL may be formed on the inner walls of the trenches TN3 and TN4, and further, the polycrystal silicon may be filled inwardly in the trenches TN3 and TN4.

In each of the above-explained embodiments, the element separating-purpose trench TN1 has been formed in such a manner that this trench TN1 passes through both the SOI layer 13 and the embedded insulating film 12 to be reached to the semiconductor supporting substrate 11, and the insulating film IL has been filled into the inner portion of the element separating-purpose trench TN1. However, if the trench TN1 may have such a structure capable of electrically separating a plurality of semiconductor devices, then a depth and a width of this trench TN1 may be arbitrarily set. For example, the structure of the element separating-purpose trench TN1 may be made similar to the structure of the diode voltage supplying-purpose trench TN2. That is to say, alternatively, the insulating film IL may be formed on the inner wall of the element separating-purpose trench TN1, and also, polycrystal silicon may be filled inwardly into the inner wall.

The structure of the semiconductor apparatus according to each of the above-described embodiments is not limited to be applied only to an N-channel lateral double diffused MOS transistor, but may be applied as a structure of a P-channel lateral double diffused MOS transistor. Concretely speaking, as shown in FIG. 15, a P well layer 50 is formed on the side of the element separating-purpose trench TN1, and an N well layer 51 is formed on the side of the diode voltage applying-purpose trench TN2 in the SOI layer 13. Then, a P-type drain higher concentration region 52 whose concentration is higher than that of this P well layer 50 is formed in the P well layer 50. On the other hand, a P type source region 53 is formed in the N well layer 51, and further, a N type contact region 54 is formed, the concentration of which is higher than that of the N well layer 51. Moreover, a drain electrode TD is formed on the drain higher concentration region 52; a source electrode TS is formed on the source region 53; and a gate electrode TG is provided via the gate insulating film l9 above the N well layer 51. Also,a voltage applied to the source electrode TS is divided by the elements 23 and 24, and this divided voltage is applied as a reverse direction voltage via the electric conductor 20 to the PN junction diode 22. If the above-explained structure is employed, then a similar effect to that of the semiconductor apparatus according to each of the respective embodiments even in the P-channel lateral double diffused MOS transistor. In this case, the structure of the P-channel lateral double diffused MOS transistor has been explained under such an initial condition that the SOI wafer WE which is used so as to manufacture the N-channel lateral double diffused MOS transistor is also utilized in order to manufacture the P-channel lateral double diffused MOS transistor. However, the structure of this P-channel lateral double diffused MOS transistor may be arbitrarily selected. For instance, in the semiconductor apparatus related to each of the embodiments, the P-channel lateral double diffused MOS transistor may be alternatively manufactured by changing a P type region into an N type region, and an N type region into a P type region.

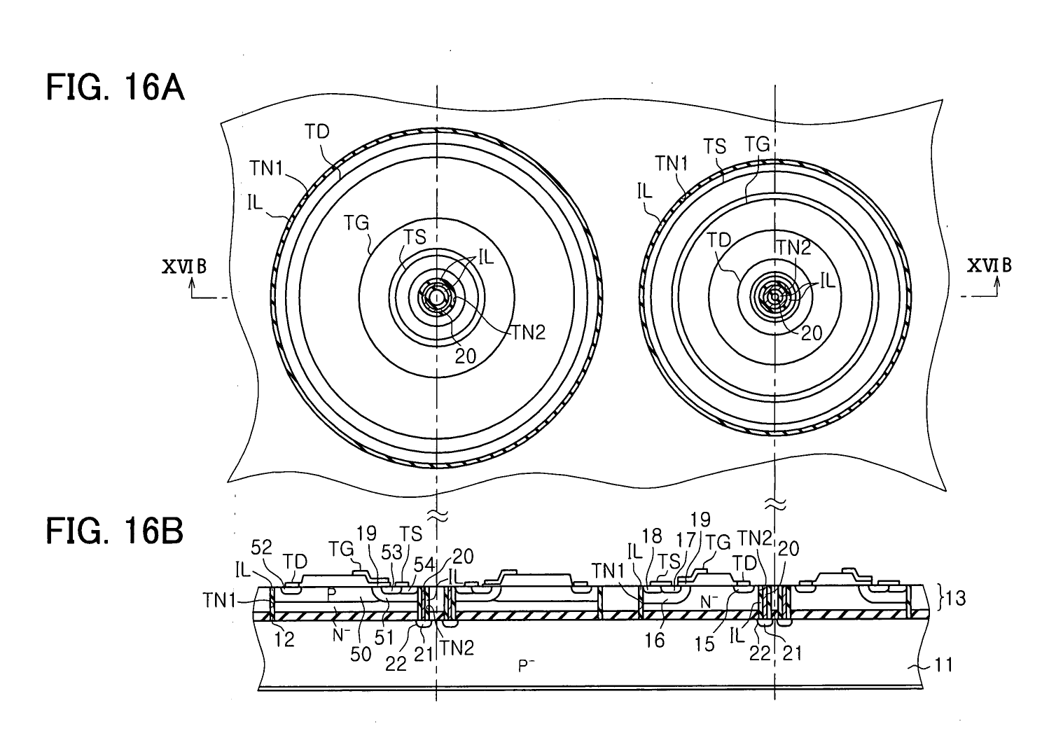

As shown in FIG. 16, both the N-channel lateral double diffused MOS transistor related to each of the above-described embodiments and the P-channel lateral double diffused MOS transistor exemplified in FIG. 15 may be alternatively integrated on the same semiconductor chip. With employment of this alternative structure, such a semiconductor apparatus (hybrid device) that a plurality of semiconductor devices such as transistors are integrated may be made compact, and also, a higher withstanding voltage of this semiconductor apparatus may be improved.

The structure of the semiconductor apparatus according to the present invention is not limited to be applied only to the lateral double diffused MOS transistor, but may be properly applied to semiconductor apparatus equipped with other semiconductor devices, for example, a diode, a JFET, an IGBT, and so on. Furthermore, the structure of the semiconductor apparatus may be properly applied to such semiconductor apparatus (hybrid devices) where plural sorts of semiconductor devices have been integrated.

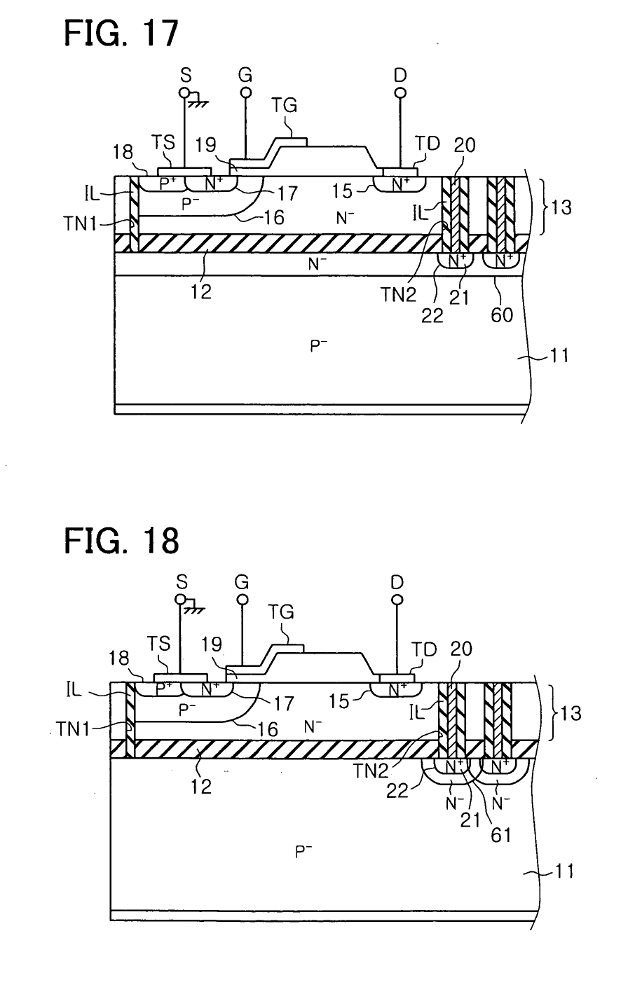

As represented in FIG. 17, an N type impurity diffused region 60 having lower concentration may be alternatively formed over an entire plane of the semiconductor supporting substrate 11 on the side of the embedded insulating film 12 in such a way that this N type impurity diffused region 60 is located deeper than the N type impurity diffused region 21. Since this N type impurity diffused region 60 having the lower concentration is employed, the electric field at the edge portion of the impurity diffused region 21 having the higher concentration may be relaxed, so that a higher withstanding voltage than that of the PN junction diode 22 may be expected. As a method of forming to N type impurity diffused region 60, in the case of a pasted SOI substrate, the N type impurity. diffused region 60 is formed over an entire plane of a semiconductor supporting substrate before being pasted. In the case of a thin-film SOI substrate (namely, thickness of SOI layer is approximately 0.01 μm to 0.3 μm ) which will be discussed later, ions may be implanted via a thin-film SOI layer (semiconductor layer) and an embedded insulating film into the thin-film SOI substrate by way of highly accelerated ion implantation so as to form the N type impurity diffused region 60 on the entire plane of the semiconductor supporting substrate.

Instead of FIG. 17, as indicated in FIG. 18, a multiple diffusion region constituted by the higher concentration impurity diffused region 21 and a lower concentration impurity diffused region 61 may be alternatively formed. A higher withstanding voltage of the PN junction diode 22 may be expected by employing the above-explained structure. As a method of forming the lower concentration impurity diffused region 61, in the case of the thin-film SOI substrate, ions may be alternatively implanted via the SOI layer and the embedded insulating film by way of the highly accelerated ion implantation. Also, while a hole which penetrates through the SOI layer and the embedded insulating film may be pierced, ions may be alternatively implanted through this hole so as to form the lower concentration impurity diffused region 61. As previously explained, as shown in FIG. 17 and FIG. 18, the semiconductor apparatus is further provided with the N type impurity diffused regions 60 and 61 which are contacted to the impurity diffused region 21 around this impurity diffused region 21 in the semiconductor supporting substrate 11, and which own the lower concentration than that of the N type impurity diffused region 21. As a result, since these N type impurity diffused region 60 and 61 having the lower concentration are employed, the electric field at the edge portion of the impurity diffused region 21 may be alternatively relaxed, so that a higher withstanding voltage than that of the PN junction diode 22 may be furthermore expected.

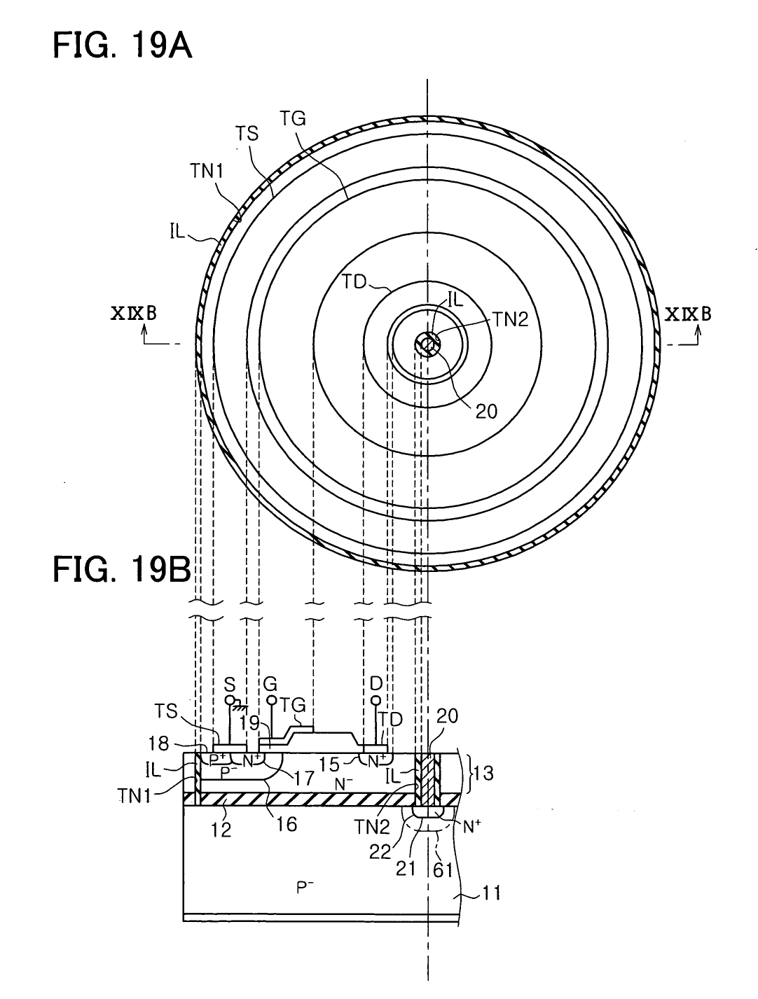

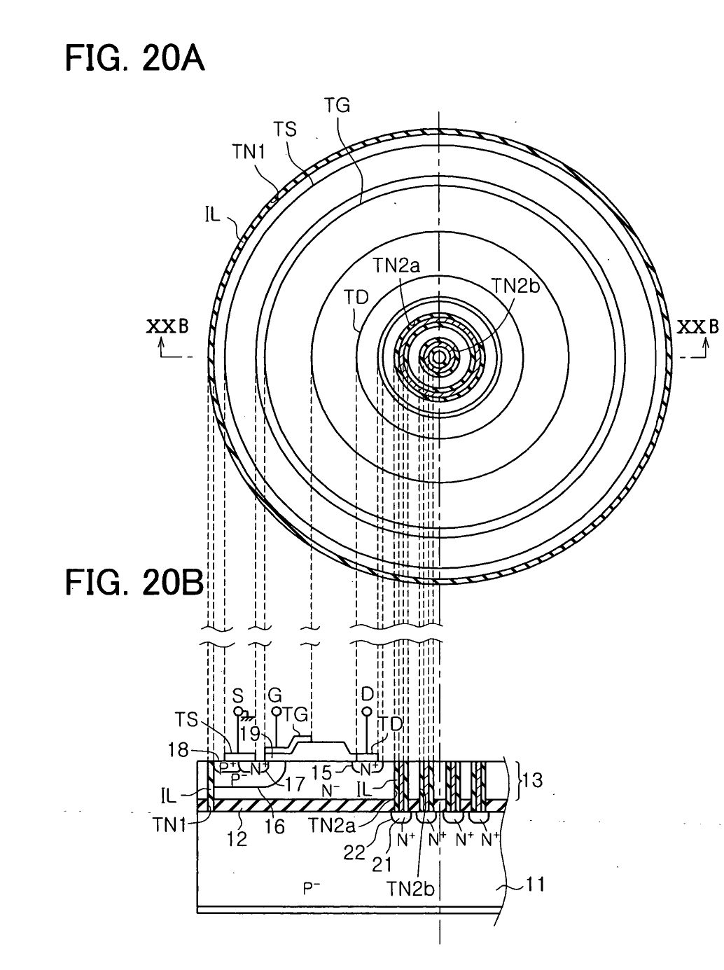

In FIG. 1A, FIG. 1B, and the like, the trench TN2 for applying the potential to the PN junction diode 22 has been formed in the ring shape. Instead of this ring shape, as represented in FIG. 19A and FIG. 19B, the trench TN2 may be alternatively made in a simple pillar shape. In this alternative case, in such a case that a curvature of the higher concentration impurity diffused region 21 becomes sharp and the withstanding voltage is lowered, the lowered withstanding voltage may be improved by forming the lower concentration impurity diffused region 61 which is broadened along the lateral direction, as compared with the higher concentration impurity diffused region 21. Alternatively, the trench TN2 for applying the potential to the PN junction diode 22 may be formed in a large number of pillars. Otherwise, as shown in FIG. 20A and FIG. 20B, the trench TN2 may be alternatively formed in a multiple ring shape made of an outer-sided ring-shaped trench TN2a and an inner-sided ring-shaped trench TN2b.

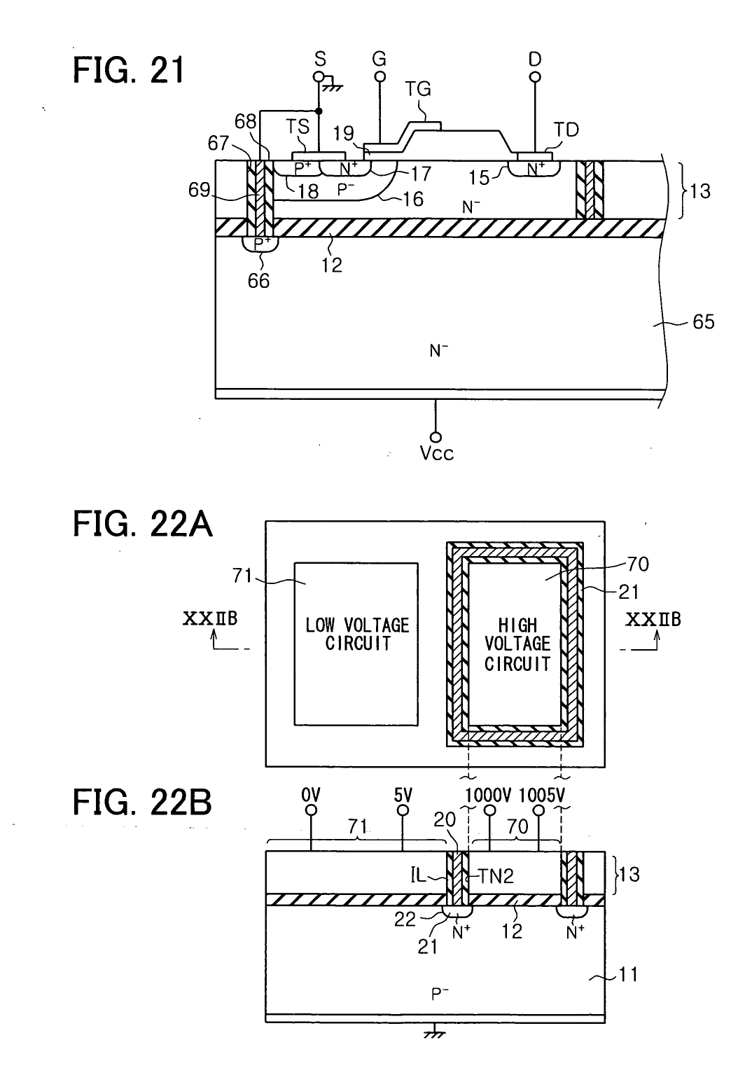

In FIG. 1A, FIG. 1B, and the like, the N⁺/P⁻ diode is employed as the PN junction diode 22. Instead of this diode, as shown in FIG. 21, a P⁺/N⁻ diode may be alternatively employed. Precisely speaking, while an N⁻supporting substrate 65 is employed as a semiconductor supporting substrate, a P⁺ region 66 is formed under a trench 67, an oxide film 68 is arranged on a side wall of the trench 67, and an electric conductor 69 is embedded inwardly within the oxide film 68. Also, a high voltage is applied to the side of the N⁻ supporting substrate 65. In other words, the P⁺ region 66 is set to a lower potential such as the ground potential (GND), whereas the N⁻ supporting substrate 65 is set to a higher potential. A lower potential region (GND etc.) of the device is formed above the P⁺ impurity diffused region 66 of the PN junction diode, and a higher potential region (drain region of N-channel transistor etc.) is formed at a place located apart from the P⁺ impurity diffused region 66.

In FIG. 1A, FIG. 1B, and the like, only the high withstanding voltage devices are described as the semiconductor apparatus according to the present invention. As indicated in FIG. 22A and FIG. 22B, a circuit (high voltage circuit 70), the terminal voltage of which is a high potential difference, may be employed with respect to the semiconductor supporting substrate 11. In FIG. 22A and FIG. 22B, a trench TN2 and an impurity diffused region 21 (PN junction diode 22) are formed in a ring shape on an outer peripheral portion of the high voltage circuit 70. At this time, the diode voltage applying-purpose trench TN2 may also have the function of the element separating-purpose trench. Apparently, in FIG. 1A and FIG. 1B, the PN junction diode 22 has been formed within the device forming region (especially, central portion). Alternatively, as shown in FIG. 22, the PN junction diode 22 may be formed in the ring shape in the outer peripheral portion of the device forming region. It should also be noted that FIG. 22A and FIG. 22B represent such an example that both the high voltage circuit 70 and a low voltage circuit 71 are formed within one chip.

As a consequence, in the case of FIG. 22A and FIG. 22B, as to the circuit 70 which is operated in the high voltage region with respect to the semiconductor supporting substrate 11, although the thickness of the embedded insulating film (oxide film) 12 must be made thick in order to secure the insulation separating withstanding voltage with respect to the supporting substrate 11, if this structure having the PN junction diode 22 is provided, then the voltage applied to the embedded oxide film can be reduced. As a result, even when such an embedded oxide film having a relatively thin thickness (for example, ½, or thinner than above-explained film) is employed, the insulation separating withstanding voltage may be realized. For instance, in the case of 1,000 V, the electric field of embedded oxidation film lower than, or equal to 5 MV/cm is preferable when reliability of the oxide film is considered. In this case, the film thickness of the embedded oxide film becomes 2 μm. However, in this structure, since the voltage may be divided by the PN junction diode 22, the embedded oxide film may be made thinner by this voltage division. Accordingly, there are merits that the semiconductor apparatus may be easily manufactured in low cost. Also, an influence given to the devices for constructing the circuit by the potential difference with respect to the potential of the semiconductor supporting substrate 11 may be reduced. This influence is defined as, for instance, a voltage depending characteristic of a resistance value of a resistive component. It should also be noted that in FIG. 1A and FIG. 1B, a high voltage series circuit may be formed inwardly in the ring-shaped trench TN2.

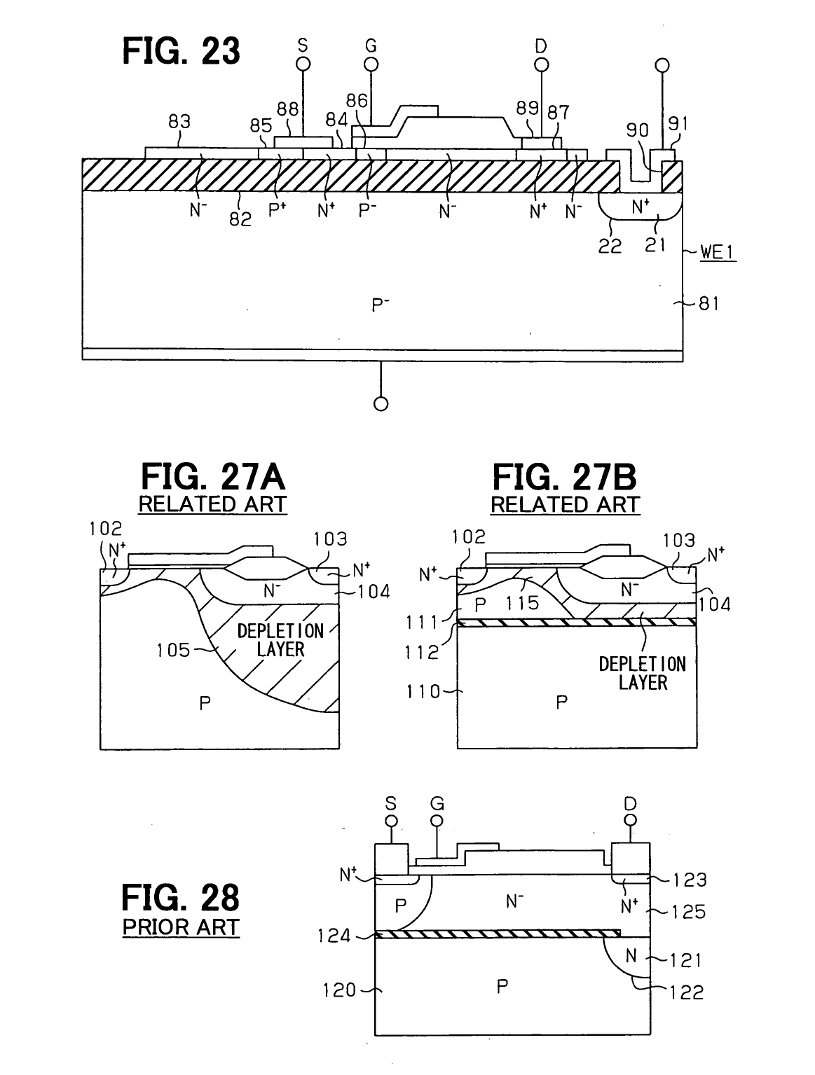

In the semiconductor apparatus and the manufacturing method thereof explained with reference to FIG. 1A, FIG. 1B, and FIG. 5 to FIG. 8, it is so predicted that the thickness of the SOI layer 13 is thicker than, or equal to a few μm . Instead of this thickness, in the case of a so-called “thin-film SOI substrate” having a thickness of approximately 0.01 μm to 0.3 μm , the below-mentioned manufacturing method may be carried out. In FIG. 23, a thin-film SOI substrate WE1 has been formed as follows: That is, a thin SOI layer 83 functioning as the semiconductor layer has been formed on a second conductor supporting substrate 81 via an embedded oxide film 82 functioning as the embedded insulating film, and then, a device, concretely speaking, a MOS transistor has been formed in the SOI layer 83. This MOS transistor has an N type source region 84, a P type contact region 85, a P type channel region 86, an N type drain higher concentration region 87, a source electrode 88, a drain electrode 89, and the like. Also, in the thin SOI layer 83, an outer peripheral portion of a device forming region (island) has been removed, and a through hole 90 which passes trough the embedded oxide film 82 has been formed in this removed region of the SOI layer 83. An N type impurity diffused region 21 used to form a PN junction diode has been formed in the P type semiconductor supporting substrate 81 at a lower plane of the through hole 90. An electrode 91 which is connected to the impurity diffused region 21 has been formed within the through hole 90 (electrode 91 for PN junction diode has been formed). A reverse direction voltage is applied via the electrode 91 to the PN junction diode.

The manufacturing steps are given as follows:

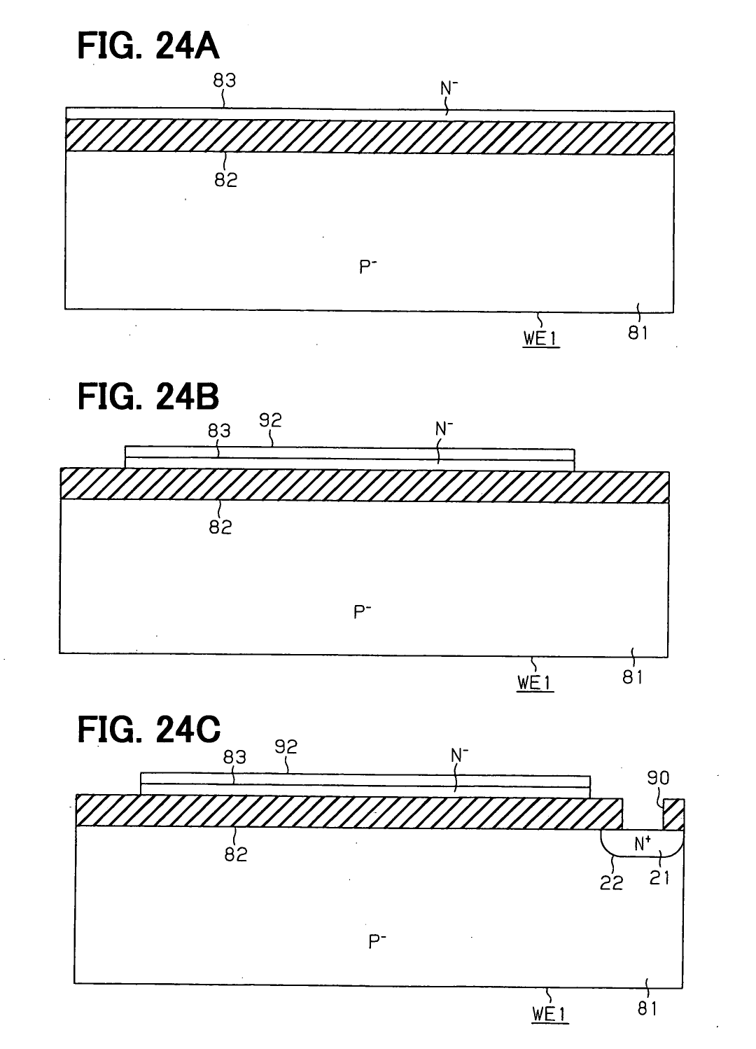

First of all, as shown in FIG. 24A, a thin-film SOI substrate WE1 is prepared in which the thin SOI layer 83 has been formed via the embedded oxide film 82 on the semiconductor supporting substrate 81. Then, as represented in FIG. 24B, after the insulating film (oxide film) 92 has been formed on the surface of the SOI layer 83, partial regions of the insulating film 92 and the SOI layer 83 are removed by way of a pattern etching process. Furthermore, as represented in FIG. 24C, a partial region of the embedded oxide film 82 is pattern-etched in the region where the SOI layer 83 has been removed so as to form the through hole 90. Then, ions are implanted via the through hole 90 into a surface layer portion of the semiconductor supporting substrate 81, and thereafter, a thermal process is carried out so as to form the impurity diffused region 21 for a PN junction diode. Subsequently, after the insulating film 92 has been removed, as represented in FIG. 23, a device is formed in the normal treating step. Precisely speaking, the source region 84, the contact region 85, the channel region 86, and the drain higher concentration region 87 are formed, and also, electrodes 88 and 89 are arranged. When electrodes of the MOS transistor are formed, an electrode 91 which is connected to the impurity diffused region 21 of the PN junction diode is formed within the through hole 90 at the same time.

As previously explained, since the thickness of the SOI layer (silicon layer) 83 is thin, in the manufacturing steps explained by employing FIG. 5 to FIG. 8, the trench TN2 is formed which passes through both the SOI layer 13 and the embedded insulating film 12, and the insulator and the electric conductor are embedded in this trench TN2, so that the potential is applied to the impurity diffused region 21 of the PN junction diode. However, in the case of FIG. 24, such a trench forming and embedding step is no longer required, so that the manufacturing steps may become easy. In other words, when an SOI layer is thick, the trench forming/embedding step is carried out. When an SOI layer is thin, even if the SOI layer is etched, a stepped portion is small before the electrodes are formed, so that the electrodes can be formed.

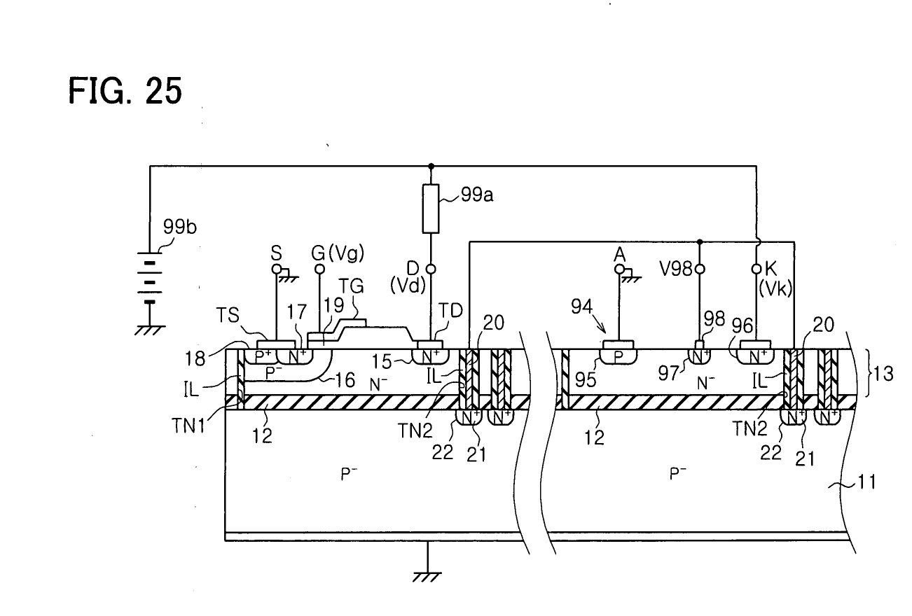

In FIG. 9A and FIG. 9B, the voltage extracting-purpose electrode 41 is formed in the drift region of the device in order to derive the voltage. Instead of this structure, as shown in FIG. 25, while a diode 94 for exclusively deriving a voltage may be formed, a reverse voltage lower than the applied voltage of the semiconductor device may be applied with respect to the PN junction diode 22 by employing this diode 94. That is to say, a P type impurity diffused region 95 and an N type higher concentration impurity diffused region 96 for a contact purpose are formed in a separate manner in the surface layer portion of the N type SOI layer 13 in a diode forming island which is different from a transistor forming island. In other words, the impurity diffused regions 95 and 96 for an anode and a cathode are formed in a separate manner in the element region separated in the SOI layer 13. Furthermore, an impurity diffused region 97 is formed in a region which constitutes a current path between the impurity diffused regions 95 and 96; an electrode 98 for extracting a voltage is formed which is contacted to this impurity diffused region 97; and a voltage extracted via the electrode 98 is applied via the electric conductor 20 as the reverse direction voltage. Precisely speaking, the voltage is applied to the anode and the cathode (impurity diffused regions 95 and 96) of the diode 94 in such a manner that a potential difference between both the anode and the cathode becomes a predetermined value, and a potential gradient is formed in the region between the impurity diffused regions 95 and 96 in connection with the application of this voltage. As a result, a desirable voltage is derived by the electrode 98. This potential is adjusted based upon the position of the impurity diffused region 97 and the voltage applied between the impurity diffused regions 95 and 96.

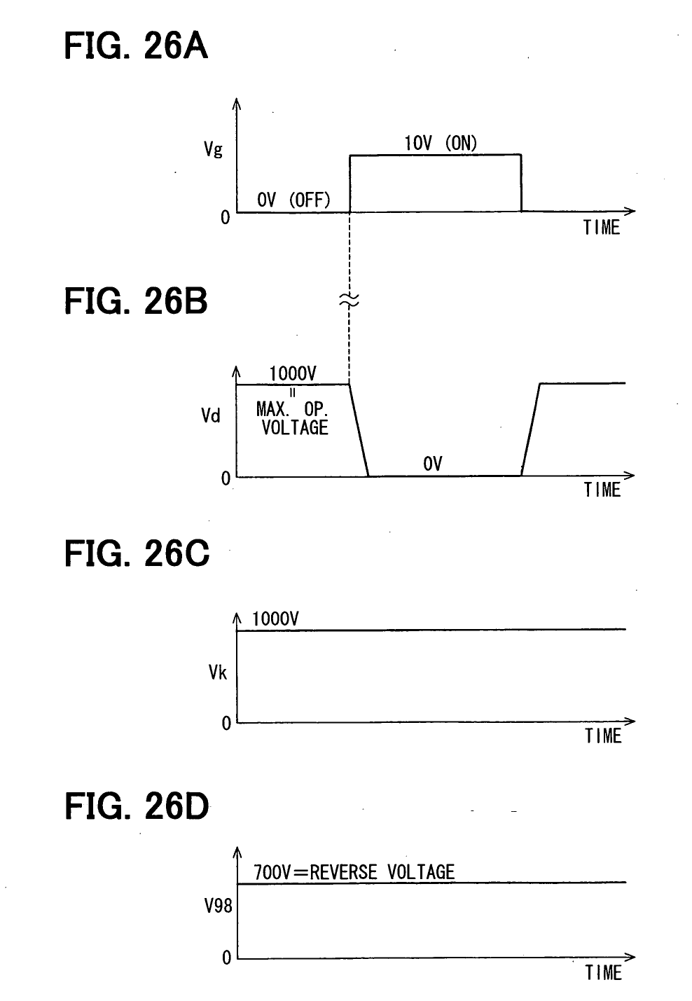

In FIG. 25, a drain terminal has been connected via a load (either inductance or resistor) 99a to a power supply 99b. Also, the cathode terminal of the diode 94 has been connected to the power supply 99b. Then, a gate voltage Vg, a drain voltage Vd, a cathode voltage Vk of the diode 94, and an applied voltage 98 to the embedded diode 22 are represented in FIGS. 26A to 26D. In FIGS. 26A to 26D, when the gate voltage Vg becomes 10 volts from zero volt, the drain voltage Vd becomes zero volt from the previous voltage of 1,000 volts. To the contrary, when the gate voltage Vg becomes zero volt from 10 volts, the drain voltage Vd becomes 1,000 volts from the previous voltage of zero volt. At this time, the cathode voltage Vk of the diode 94 is continuously 1,000 volts, and the applied voltage V98 to the embedded diode 22, namely, the reverse direction voltage is continuously 700 volts. In other words, such a reverse direction voltage (700 volts in FIG. 26D) which is lower than a maximum operation voltage (1,000 volts in FIGS. 26B and 26C) applied to the drain terminal is applied to the PN junction diode 22.

As previously explained, in FIG. 1A and FIG. 1B and the like, in such a case that the drain voltage is divided and the divided voltage is applied to the PN junction diode 22, the voltage lower than the drain voltage is continuously applied as the reverse direction voltage. However, in the case of FIG. 25, while the independent power supply is employed, the drain voltage is operated between the maximum voltage and the zero volt, and the fixed potential is applied to the diode 22 formed in the supporting substrate 11. As a consequence, while considering the case of FIG. 1A and FIG. 1B and the case of FIG. 25, the reverse voltage which is lower than the maximum operation voltage applied to the semiconductor device may be applied to the PN junction diode 22. The reverse direction voltage corresponds to 700 volts in FIG. 26D, and corresponds to a voltage in response to the drain voltage lower than or equal to 700 volts in FIG. 1A and FIG. 1B. The maximum operating voltage corresponds to 1,000 volts in FIGS. 26B and 26C and also in FIG. 1A and FIG. 1B.

It should also be noted that in FIG. 1B, FIG. 9B, FIG. 10B, FIG. 14, FIG. 15, FIG. 17, FIG. 18, FIG. 19B, FIG. 20B, FIG. 21, and FIG. 25, either the sources or the drains are connected to the ground, but need not be always connected to the ground.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A semiconductor device comprising:
a semiconductor support substrate having a first conductive type;
an insulation layer disposed on the substrate;
a semiconductor layer disposed on the insulation layer;
a semiconductor element disposed in the semiconductor layer; and
a first impurity diffusion region having a second conductive type, wherein
the first impurity diffusion region is disposed in the substrate, contacts the insulation layer, and isolated from the semiconductor layer with the insulation layer,
the first impurity diffusion region and the substrate provide a PN junction diode,
the semiconductor element has a maximum operation voltage, and
the PN junction diode has an applied voltage, which is applied to the PN junction diode opposite to a forward voltage of the PN junction diode and lower than the maximum operation voltage of the semiconductor element.

2. The device according to claim 1, wherein
the maximum operation voltage is divided to a predetermined voltage, and
the divided voltage is the applied voltage of the PN junction diode.

3. The device according to claim 1, further comprising:
a conductor disposed in a first trench through a first insulation film, wherein
the conductor penetrates the semiconductor layer and the insulation layer and connects to the first impurity diffusion region,
the conductor is isolated from the semiconductor layer with the first insulation film, and
the applied voltage is capable of being applied to the PN junction diode through the conductor.

4. The device according to claim 3, wherein the conductor is made of poly crystal semiconductor material.

5. The device according to claim 3, further comprising:
an electrode for extracting a predetermined voltage, wherein
the electrode is disposed in a drift region as a current path in the semiconductor element, and
the extracted voltage is the applied voltage of the PN junction diode.

6. The device according to claim 3, further comprising:
a second insulation film in a second trench, wherein
the second trench penetrates the semiconductor layer and reaches the insulation, and
the second insulation film surrounds the conductor.

7. The device according to claim 1, further comprising:
a second impurity diffusion region having the second conductive type, wherein
the second impurity diffusion region has an impurity concentration lower than that of the first impurity diffusion region, and
the second impurity diffusion region is disposed around the first impurity diffusion region in the substrate in such a manner that the second impurity diffusion region contacts the first impurity diffusion region.

8. The device according to claim 3, further comprising:
a separation part disposed in the semiconductor layer and separated from the semiconductor element;
an anode impurity diffusion region for an anode disposed in the separation part;
a cathode impurity diffusion region for a cathode disposed in the separation part;
an electrode for extracting a predetermined voltage, wherein
the electrode is disposed in a current path between the anode impurity diffusion region and the cathode impurity diffusion region, and
the extracted voltage is the applied voltage of the PN junction diode.

9. The device according to claim 3, further comprising:
a separation insulation film in a separation trench, wherein
the separation trench penetrates the semiconductor layer and reaches the insulation layer, and
the separation insulation film surrounds the semiconductor element and the conductor so that the semiconductor element is isolated by the separation insulation film and the insulation layer.

10. The device according to claim 9, wherein
the semiconductor element is a lateral double-diffused MOS transistor, and
the maximum operation voltage of the semiconductor element is a drain voltage of the MOS transistor.

11. A method for manufacturing the device according to claim 3, the method comprising:
forming the insulation layer on the substrate;
forming the semiconductor layer on the insulation layer;
forming the first trench to penetrate the semiconductor layer and the insulation layer and to reach the substrate;
forming the first insulation film on an inner wall of the first trench;
removing a part of the first insulation film, which is disposed on a bottom of the first trench;
filling the first trench with poly crystal semiconductor material having the second conductive type; and
diffusing a second conductive type impurity in the poly crystal semiconductor material into the substrate in order to form the first impurity diffusion region.
